(19) United States
(12) Patent Application Publication
(10) Pub. No.: US 2023/0350300 A1
(43) Pub. Date: Nov. 2, 2023

(54) SUBSTRATE PROCESSING APPARATUS AND SUBSTRATE FLOATING AMOUNT MEASUREMENT METHOD

(71) Applicant: SEMES CO., LTD., Cheonan-si (KR)

(72) Inventor: Byeong Min LEE, Cheonan-si (KR)

(73) Assignee: SEMES CO., LTD., Cheonan-si (KR)

(21) Appl. No.: 18/300,912

(22) Filed: Apr. 14, 2023

(30) Foreign Application Priority Data
May 2, 2022 (KR) 10-2022-0054387

(51) Int. Cl. G03F 7/20; G03F 7/16; G03F 7/00

(52) U.S. Cl. CPC G03F 7/16; G03F 7/2053; G03F 7/70653; G03F 7/706835; G03F 7/708

(57) ABSTRACT

Provided is a substrate processing apparatus including a substrate floating unit for floating a substrate, a nozzle unit positioned above the substrate floating unit to eject a liquid chemical onto the substrate, a measurement unit for measuring a floating amount of the substrate, and a controller for obtaining a serial number of the substrate and providing control to change, based on the serial number, reference signal data used by the measurement unit to measure the floating amount of the substrate.

### CROSS-REFERENCE TO RELATED PATENT APPLICATION

This application claims the benefit of Korean Patent Application No. 10-2022-0054387, filed on May 02, 2022, in the Korean Intellectual Property Office, the disclosure of which is incorporated herein in its entirety by reference.

### BACKGROUND OF THE INVENTION

### 1. Field of the Invention

The present invention relates to a semiconductor apparatus and, more particularly, to a substrate processing apparatus and a substrate floating amount measurement method.

### 2. Description of the Related Art

To manufacture semiconductor devices or displays, various processes for supplying a liquid chemical onto a substrate, e.g., photolithography, etching, ion implantation, deposition, and cleaning, are performed. Among these processes, photolithography is a process for forming a desired pattern on the substrate. The photolithography process includes a coating process for coating a photosensitive solution such as a photoresist on the substrate, an exposure process for forming a specific pattern on the coated photosensitive layer, and a development process for removing a specific region from the exposed photosensitive layer.

Among the above processes, in the coating process, a liquid chemical is ejected from a nozzle onto the substrate while the substrate is being transferred in one direction. The substrate may be moved using a substrate floating device having holes for providing a floating force capable of floating the substrate. The substrate may be moved and the liquid chemical such as a photoresist may be ejected onto the substrate while the substrate is floated by providing a gas pressure or vacuum pressure from below the substrate.

A floating amount or floating height of the substrate needs to be managed within a set range. When the floating amount or floating height of the substrate exceeds the set range, because a thin layer formed by ejecting the liquid chemical is not uniform to cause defects, the floating amount of the substrate onto which the liquid chemical is ejected is precisely managed.

### SUMMARY OF THE INVENTION

In general, a floating amount of a substrate is measured using a beam irradiated onto the substrate from a laser displacement sensor disposed above the substrate. The laser displacement sensor measures the floating amount by using a displacement between a height at which the substrate is positioned on the bottom of a substrate floating device and a height to which the substrate is floated. However, when the laser beam is irradiated onto the substrate, various types of layers may have been deposited on the substrate. Because reflectivity for the irradiated laser beam varies depending on the type of the deposited layer, a beam signal received by the laser displacement sensor also varies depending on the type of the substrate. As such, a technology for accurately measuring floating amounts of various substrates is required.

The present invention provides a substrate processing apparatus and substrate floating amount measurement method capable of precisely measuring a floating amount regardless of the type of a layer formed on a substrate.

The present invention also provides a substrate processing apparatus and substrate floating amount measurement method capable of preventing a measurement error due to a reflectivity of a substrate by minimizing a procedure of setting a zero point of a floating amount measurement apparatus, which needs to be performed based on the type of the substrate.

The present invention also provides a substrate processing apparatus and substrate floating amount measurement method capable of preventing process failure by precisely measuring a floating amount and thoroughly monitoring every process.

However, the scope of the present invention is not limited thereto.

According to an aspect of the present invention, there is provided a substrate processing apparatus including a substrate floating unit for floating a substrate, a nozzle unit positioned above the substrate floating unit to eject a liquid chemical onto the substrate, a measurement unit for measuring a floating amount of the substrate, and a controller for obtaining a serial number of the substrate and providing control to change, based on the serial number, reference signal data used by the measurement unit to measure the floating amount of the substrate.

The measurement unit may measure the floating amount of the substrate by measuring a reflected signal of a beam irradiated onto the substrate.

The measurement unit may measure the floating amount of the substrate by measuring a signal of the beam from a height at which the substrate is in contact with the substrate floating unit to a height to which the substrate is floated.

The measurement unit may irradiate a laser beam onto the substrate.

The reference signal data may be set based on a difference in reflectivity for the beam between layers formed on different substrates.

The controller may measure floating amounts of substrates having the same serial number, by applying the same reference signal data.

When reference signal data corresponding to a specific serial number of the substrate does not exist, the controller may measure a signal of the beam from a height at which the substrate is in contact with the substrate floating unit to a height to which the substrate is floated, and set a displacement of the beam due to a change of the substrate as reference signal data for the serial number.

All substrates may be controlled to be floated to the same height, and different reference signal data may be set for different serial numbers.

The controller may set reference signal data for the serial number of the substrate and, when reference signal data corresponding to a specific serial number exists, the measurement unit may measure the floating amount of the substrate by applying the reference signal data.

The substrate floating unit may include a stage having a top surface provided with a plurality of holes, and a pressure providing member for providing a gas pressure or vacuum pressure through the holes to above the stage.

The stage may include a loader, a coater, and an unloader, and the nozzle unit may eject the liquid chemical onto the substrate from above the coater.

At least one measurement unit may be disposed above the coater.

When reference signal data corresponding to a specific serial number of the substrate does not exist, the measurement unit used to set the reference signal data may be disposed above the loader or above a path on the coater before the nozzle unit.

According to another aspect of the present invention, there is provided a method of measuring a floating amount of a substrate in a substrate processing apparatus including a substrate floating unit for floating the substrate, a nozzle unit positioned above the substrate floating unit to eject a liquid chemical onto the substrate, and a measurement unit for measuring the floating amount of the substrate, the method including obtaining a serial number of the substrate, and providing control to change, based on the serial number, reference signal data used by the measurement unit to measure the floating amount of the substrate.

The floating amount of the substrate may be measured by irradiating a beam onto the substrate and measuring a reflected signal by using the measurement unit.

The reference signal data may be set based on a difference in reflectivity for the beam between layers formed on substrates having different serial numbers.

Floating amounts of substrates having the same serial number may be measured by applying the same reference signal data.

The method may further include (a) obtaining the serial number of the substrate, (b) determining whether reference signal data corresponding to the serial number of the substrate exists, and (c) measuring, by the measurement unit, the floating amount of the substrate by applying the reference signal data corresponding to the serial number, and step (b) may include, when the reference signal data corresponding to the serial number of the substrate does not exist, measuring a signal of a beam from a height at which the substrate is in contact with the substrate floating unit to a height to which the substrate is floated, and setting a displacement of the beam due to a change of the substrate as reference signal data for the serial number.

The method may further include (d) adjusting the floating amount of the substrate in such a manner that all substrates are floated to the same height.

According to another aspect of the present invention, there is provided a method of measuring a floating amount of a substrate in a substrate processing apparatus including a substrate floating unit for floating the substrate, a nozzle unit positioned above the substrate floating unit to eject a liquid chemical onto the substrate, and a measurement unit for measuring the floating amount of the substrate, the method including (a) obtaining a serial number of the substrate, (b) determining whether reference signal data corresponding to the serial number of the substrate exists, and (c) measuring, by the measurement unit, the floating amount of the substrate by applying the reference signal data corresponding to the serial number, wherein step (c) includes measuring the floating amount of the substrate by irradiating a laser beam onto the substrate and measuring a reflected signal by using the measurement unit, wherein the reference signal data is set based on a difference in reflectivity for the laser beam between layers formed on substrates having different serial numbers, wherein step (b) includes, when the reference signal data corresponding to the serial number of the substrate does not exist, measuring a signal of the laser beam from a height at which the substrate is in contact with the substrate floating unit to a height to which the substrate is floated, and setting a displacement of the laser beam due to a change of the substrate as reference signal data for the serial number, and wherein floating amounts of substrates having the same serial number are measured by applying the same reference signal data.

### BRIEF DESCRIPTION OF THE DRAWINGS

The above and other features and advantages of the present invention will become more apparent by describing in detail embodiments thereof with reference to the attached drawings in which:

FIG. 1 is a perspective view of a substrate processing apparatus according to an embodiment of the present invention;

FIG. 2 is a plan view of a substrate processing apparatus according to an embodiment of the present invention;

FIG. 3 is a cross-sectional view cut along line X-X′ of the substrate processing apparatus of FIG. 2;

FIG. 4 includes cross-sectional views showing a general procedure of setting reference signal data of a measurement unit by using bare glass;

FIG. 5 is a cross-sectional view showing problems caused in a general procedure of measuring floating amounts of substrates on which various layers are formed;

FIG. 6 includes cross-sectional views showing a substrate transfer procedure and a floating amount measurement procedure, according to an embodiment of the present invention;

FIG. 7 includes cross-sectional views showing a substrate transfer procedure and a floating amount measurement procedure, according to another embodiment of the present invention;

FIG. 8 is a flowchart of a substrate floating amount measurement method according to an embodiment of the present invention; and

FIG. 9 is a flowchart of a substrate floating amount adjustment method according to an embodiment of the present invention.

### DETAILED DESCRIPTION OF THE INVENTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity and convenience of explanation.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

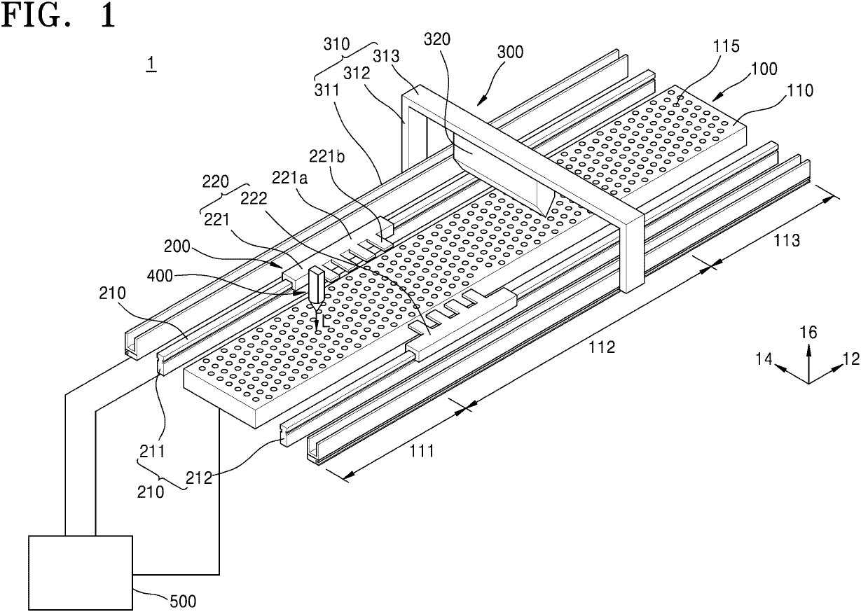

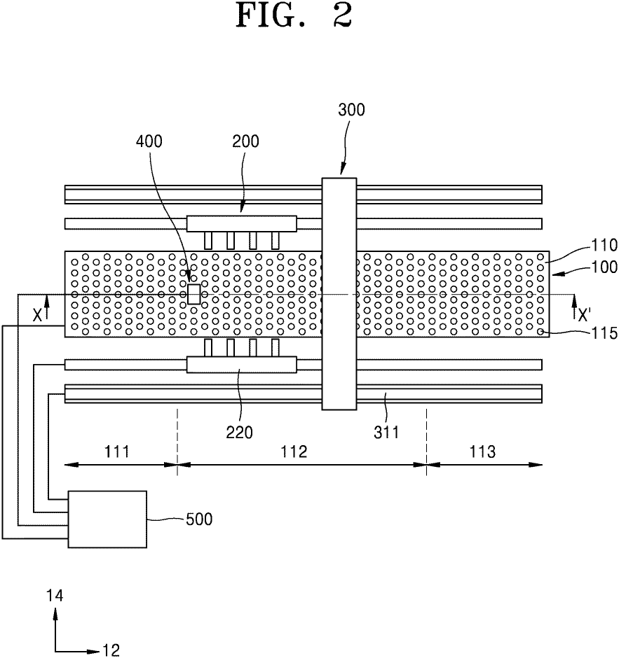

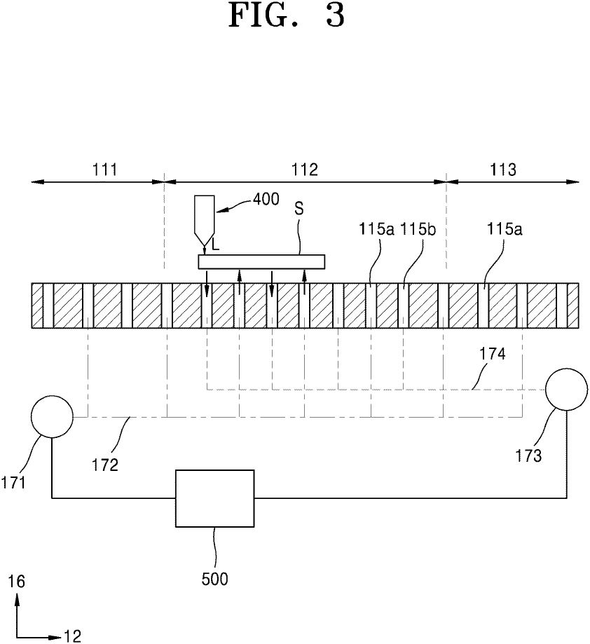

FIG. 1 is a perspective view of a substrate processing apparatus 1 according to an embodiment of the present invention. FIG. 2 is a plan view of the substrate processing apparatus 1 according to an embodiment of the present invention. FIG. 3 is a cross-sectional view cut along line X-X′ of the substrate processing apparatus 1 of FIG. 2.

Referring to FIGS. 1 to 3, the substrate processing apparatus 1 includes a substrate floating unit 100, a substrate moving unit 200, a nozzle unit 300, a measurement unit 400, and a controller 500. In this specification, a first direction 12 may correspond to an x-axis direction, a second direction 14 may correspond to a y-axis direction, and a third direction 16 may correspond to a z-axis direction.

The substrate floating unit 100 includes a stage 110 and a pressure providing member 170. The stage 110 is provided in such a manner that a longitudinal direction thereof extends along the first direction 12. The stage 110 may be provided in a flat panel shape having a certain thickness. The stage 110 includes a loader 111, a coater 112, and an unloader 113. The loader 111, the coater 112, and the unloader 113 are sequentially provided in the first direction 12 from an end of the stage 110. According to an embodiment, the loader 111, the coater 112, and the unloader 113 may be provided as separate stages. In this case, the stages provided as the loader 111, the coater 112, and the unloader 113 may be combined into one stage 110. Unlike this, one stage 110 may be divided into regions of the loader 111, the coater 112, and the unloader 113.

The stage 110 has a plurality of holes 115 in a top surface thereof. The plurality of holes 115 include gas holes 115a for providing a gas pressure, and vacuum holes 115b for providing a vacuum pressure. The plurality of holes 115 may be provided in different numbers in the loader 111, the coater 112, and the unloader 113. According to an embodiment, the coater 112 may be provided with a larger number of holes 115 per unit area compared to the loader 111 and the unloader 113. Unlike this, the loader 111, the coater 112, and the unloader 113 may be provided with equal numbers of holes 115. Optionally, no vacuum holes 115b may be provided in the loader 111 and the unloader 113.

The stage 110 includes a plurality of floating zones on the top surface thereof. According to an embodiment, the coater 112 may include a plurality of floating zones on a top surface thereof. Each of the loader 111 and the unloader 113 may include only one floating zone. The plurality of floating zones may have the same length in the first direction 12. The plurality of holes 115 are arranged at regular intervals in each floating zone. Unlike this, a plurality of floating zones may also be provided on each of the loader 111 and the unloader 113.

For example, the floating zones may be provided in such a manner that the plurality of holes 115 form equal numbers of rows. The plurality of holes 115 may be provided parallel to the first direction 12. As another example, the floating zones may be provided in such a manner that the plurality of holes 115 form different numbers of rows. As such, a floating pressure may be uniformly provided to the entirety of a bottom surface of a substrate S to be transferred.

The pressure providing member 170 is connected to the holes 115 provided in the top surface of the stage 110. The pressure providing member 170 provides a gas pressure or vacuum pressure to the holes 115. The pressure providing member 170 includes a gas pressure providing member 171, a gas pressure providing line 172, a vacuum pressure providing member 173, and a vacuum pressure providing line 174.

The gas pressure providing member 171 generates a gas pressure. The gas pressure providing member 171 may generate a pressure by providing air or nitrogen. The gas pressure providing member 171 may be positioned outside the stage 110. Unlike this, the gas pressure providing member 171 may be positioned inside the stage 110. The gas pressure providing line 172 connects the gas pressure providing member 171 to the gas holes 115a.

The vacuum pressure providing member 173 generates a vacuum pressure. The vacuum pressure providing member 173 may be positioned outside the stage 110. Unlike this, the vacuum pressure providing member 173 may be positioned inside the stage 110. The vacuum pressure providing member 173 provides a vacuum pressure by using a pump (not shown) or the like. The vacuum pressure providing line 174 connects the vacuum pressure providing member 173 to the vacuum holes 115b. According to an embodiment, the vacuum pressure providing line 174 may be provided to be connected only to the holes 115 of the coater 112.

The substrate moving unit 200 includes guide rails 210 and a grabbing member 220. The substrate moving unit 200 grabs the substrate S above the stage 110 and moves the substrate S in the first direction 12.

The guide rails 210 are provided to extend in the first direction 12 parallel to the stage 110. The guide rails 210 include a first guide rail 211 and a second guide rail 212. The first guide rail 211 is positioned at a left side of the first direction 12 from the stage 110. The second guide rail 212 is positioned at a right side of the first direction 12 from the stage 110. The first and second guide rails 211 and 212 are provided at symmetrical positions about the stage 110.

The grabbing member 220 includes a first grabbing member 221 and a second grabbing member 222. The first and second grabbing members 221 and 222 grab both sides of the substrate S in the second direction 14. The first grabbing member 221 includes a body 221a and grabbers 221b. The body 221a is in contact with the first guide rail 211.

The body 221a may move in the first direction 12 along the first guide rail 211. The grabbers 221b are provided to protrude toward the stage 110 from a right side of the body 221a. A plurality of grabbers 221b may be provided. The grabbers 221b are positioned above the top surface of the stage 110 to grab the substrate S floating above the stage 110. According to an embodiment, the grabbers 221b may grab the substrate S by providing vacuum to the bottom surface of the substrate S. Unlike this, the grabbers 221b may grab the substrate S in a mechanical manner. The second grabbing member 222 includes a body and grabbers. The second grabbing member 222 has the same configuration as the first grabbing member 221. The second grabbing member 222 is provided at a position symmetrical to the first grabbing member 221 about the stage 110.

The nozzle unit 300 includes a nozzle moving member 310 and a nozzle 320. The nozzle unit 300 ejects a liquid chemical onto a top surface of the substrate S.

The nozzle moving member 310 includes nozzle guide rails 311, vertical frames 312, and a support bar 313. The nozzle guide rails 311 are provided outside the guide rails 210. The nozzle guide rails 311 are provided to extend in the first direction 12 parallel to the guide rails 210. The vertical frames 312 connect the nozzle guide rails 311 to the support bar 313. Lower ends of the vertical frames 312 are connected to the nozzle guide rails 311. As such, the vertical frames 312 may move in the first direction 12 on the nozzle guide rails 311. Both ends of the support bar 313 are connected to upper ends of the vertical frames 312. The support bar 313 is provided in such a manner that a longitudinal direction thereof extends along the second direction 14. The nozzle 320 is positioned on a bottom surface of the support bar 313.

The nozzle 320 is provided in such a manner that a longitudinal direction thereof extends along the second direction 14. The nozzle 320 has one or more surfaces coupled to the support bar 313 so as to be positioned above the stage 110 in the third direction 16. The nozzle 320 ejects the liquid chemical onto the substrate S. The liquid chemical may be provided as a photosensitive solution, and more specifically, as a photoresist.

Optionally, when the nozzle 320 ejects the liquid chemical at a fixed position, the nozzle guide rails 311 may not be provided.

Meanwhile, the nozzle 320 may be provided as a nozzle included in an inkjet printing apparatus, and an inkjet print head may be provided as the nozzle unit 300.

The measurement unit 400 is provided to measure a floating amount or floating height of the substrate S. The measurement unit 400 may measure the floating amount by irradiating a beam onto the substrate S and receiving a beam reflected from the substrate S. The measurement unit 400 may include a beam generator (not shown) for generating a beam, and a beam receiver (not shown) for receiving a reflected beam. For example, the measurement unit 400 may include a laser displacement sensor using a laser beam.

The measurement unit 400 may set a height at which the substrate S is in contact with or adsorbed on the stage 110 of the substrate floating unit 100, as a bottom dead point and measure a height to which the substrate S is floated from the top surface of the stage 110.

One or more measurement units 400 may be provided. The measurement unit 400 may be disposed above the coater 112 to continuously measure the floating amount of the substrate S in the liquid chemical ejection procedure of the nozzle 320. However, the measurement unit 400 is not limited thereto and may also be disposed above the loader 111. The measurement unit 400 disposed above the loader 111 may be used to set reference signal data to be described below. The measurement unit 400 for setting the reference signal data may be disposed above a path before the nozzle unit 300 in a path along which the substrate S is transferred.

The controller 500 may provide a series of controls to the elements of the substrate processing apparatus 1. For example, the controller 500 may control the pressure providing member 170 to provide a gas pressure or vacuum pressure to the holes 115. In addition, the controller 500 may control a value of the gas pressure or vacuum pressure. As another example, the controller 500 may control operation of the grabbing member 220 of the substrate moving unit 200. The controller 500 may control the procedure in which the grabbing member 220 of the substrate moving unit 200 grabs the substrate S and moves along the guide rails 210. As another example, the controller 500 may control an amount and a position by and to which the liquid chemical is ejected from the nozzle unit 300 onto the substrate S. As another example, the controller 500 may control the measurement unit 400 to irradiate a beam L onto the substrate S, analyze a signal of a beam reflected from the substrate S, and calculate a floating amount or floating height of the substrate S. The controller 500 may store a serial number of the substrate S, reference signal data set for operation of the measurement unit 400, etc.

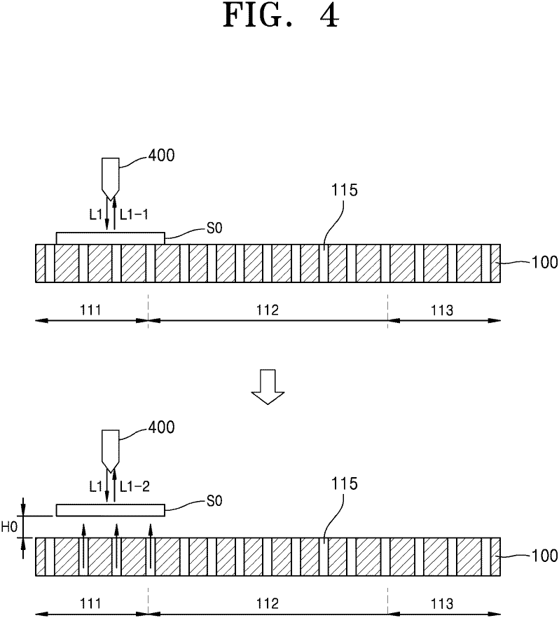

Particularly, the substrate processing apparatus 1 of the present invention is characterized in that the controller 500 obtains a serial number of the substrate S and provides control to change, based on the serial number, reference signal data used by the measurement unit 400 to measure a floating amount of the substrate S. A detailed description thereof will now be provided with reference to FIGS. 4 to 7.

FIG. 4 includes cross-sectional views showing a general procedure of setting reference signal data of the measurement unit 400 by using bare glass S0.

Referring to FIG. 4, in general, the bare glass S0 is used to set the reference signal data of the measurement unit 400. The bare glass S0 may use a glass substrate on which no layer or a specific layer is formed. The bare glass S0 may be provided as a substrate for adjusting a zero point of the measurement unit 400. The reference signal data is set in the procedure of adjusting the zero point of the measurement unit 400.

The reference signal data corresponds to a parameter for comparing and correcting an intensity of a beam L1 irradiated from the measurement unit 400 onto the substrate S and an intensity of a reflected beam L1-1. From a different point of view, the reference signal data may correspond to zero point data of the measurement unit 400 for measuring a floating amount or floating height of the substrate S. For example, when the beam L1 corresponding to a value of 100 is irradiated onto the substrate S and a value of the reflected beam L1-1 is 95, the reference signal data may be understood as zero point data or a parameter for correcting the beam L1 to 95%.

Referring to the upper view of FIG. 4, the bare glass S0 is disposed on the substrate floating unit 100 (or the stage 110). The bare glass S0 may be in contact with or adsorbed on the substrate floating unit 100. The bare glass S0 may be positioned at a bottom dead point or a bottom point in terms of height. In this state, the measurement unit 400 irradiates the beam L1 and measures a signal of the beam L1-1 reflected from the bare glass S0.

Then, referring to the lower view of FIG. 4, the bare glass S0 is floated. An irradiated beam L1 and a signal of a reflected beam L1-2 may be measured based on a floating amount or floating height H0 of the substrate S. When a height of the measurement unit 400 is fixed, a change in beam intensity (L1-1 → L1-2) based on a change in distance between the measurement unit 400 and the substrate S or a change in beam intensity (L1-1 → L1-2) before and after the substrate S is floated may correspond to the floating amount or floating height H0 of the substrate S. When the height of the measurement unit 400 varies, a change in beam intensity (L1-1 → L1-2) before and after the substrate S is floated may correspond to the floating amount or floating height H0 of the substrate S.

The controller 500 may obtain the reference signal data based on a difference between the irradiated beam L1 and the reflected beam L1-1 shown in the upper view of FIG. 4. Alternatively, the controller 500 may obtain the reference signal data based on a displacement between the signal of the beam L1-1 reflected when the substrate S is positioned at the bottom dead point and the signal of the beam L1-2 reflected when the substrate S is floated as shown in the lower view of FIG. 4. The reference signal data may also be obtained by combining the above two procedures.

After the substrate processing apparatus 1 is initially set by obtaining the reference signal data by using the bare glass S0 based on the procedure of FIG. 4, a floating amount of the substrate S is measured using the reference signal data in a subsequent substrate transfer process.

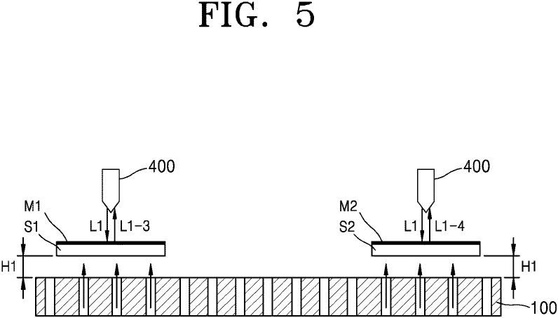

FIG. 5 is a cross-sectional view showing problems caused in a general procedure of measuring floating amounts of substrates on which various layers are formed.

Various types of layers are formed on the substrate S in a procedure of transferring and coating the substrate S. For example, a metal layer such as a copper (Cu) or aluminum (Al) layer usable as wirings may be formed on the substrate S. As another example, a layer such as an active silicon layer or a silicon oxide layer may be formed on the substrate S. Various types of layers exhibit different beam reflectivities.

According to an embodiment, with respect to an irradiated beam L1, a signal of a beam L1-3 reflected from a substrate S1 on which a metal layer M1 is formed differs from a signal of a beam L1-4 reflected from a substrate S2 on which a silicon layer M2 is formed, because the layers M1 and M2 exhibit different reflectivities for the irradiated beam L1. For example, when a value of the reflected beam L1-3 is 97 with respect to the irradiated beam L1 corresponding to a value of 100, the metal layer M1 exhibits an error of about 2% compared to reference signal data for correction to 95% on the basis of the bare glass S0. As another example, when a value of the reflected beam L1-4 is 92 with respect to the irradiated beam L1 corresponding to a value of 100, the silicon layer M2 exhibits an error of about 3% compared to reference signal data for correction to 95% on the basis of the bare glass S0. Furthermore, in the above examples, an error of about 5% may occur between the metal layer M1 and the silicon layer M2.

When the substrate S is coated using the nozzle unit 300, a vertical distance between the nozzle 320 and the substrate S is about several hundreds of µm, and a thickness of a coated layer is about several µm. As described above, the difference between the signals of the beams L1-3 and L1-4 due to the difference in beam reflectivity between the layers M1 and M2 may cause a height measurement error of several µm to several tens of µm of the measurement unit 400. Eventually, the floating amount measurement error of several µm to several tens of µm may cause an error in thickness of a desired coated layer and seriously exert an adverse effect on process stability. In addition, when a process is performed by measuring the floating amount of the substrate S to be less than an actual floating amount, the substrate S moving to a height greater than a set height may collide with the nozzle 320.

Therefore, the present invention is characterized in that reference signal data fixed by the bare glass S0 is not used but is flexibly changed based on the type of the substrate S or the type of a layer formed on the substrate S.

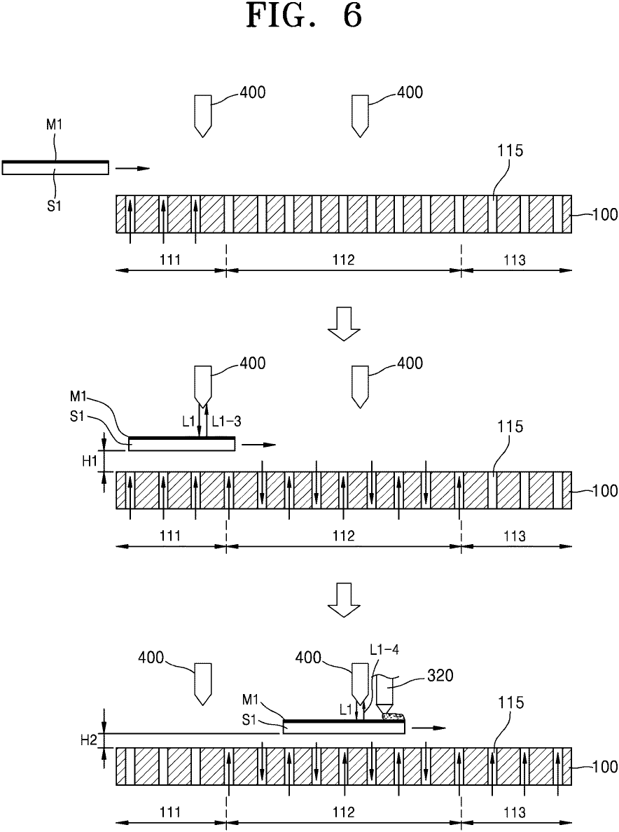

FIG. 6 includes cross-sectional views showing a substrate transfer procedure and a floating amount measurement procedure, according to an embodiment of the present invention.

Initially, the controller 500 may obtain a serial number of a substrate S. The serial number may be a number reflecting a pre-process performed before the substrate S enters the substrate processing apparatus 1. The serial number may include a combination of numbers, characters, and symbols. When substrates have the same serial number, it may be understood that the same process has been performed on the substrates. That is, the substrates having the same serial number may be understood as substrates S1 on which the same layer M1 is formed. From a different point of view, the substrates having the same serial number may be understood as having the same reflectivity for the irradiated beam L1 and having the same intensity of the reflected beam L1-3.

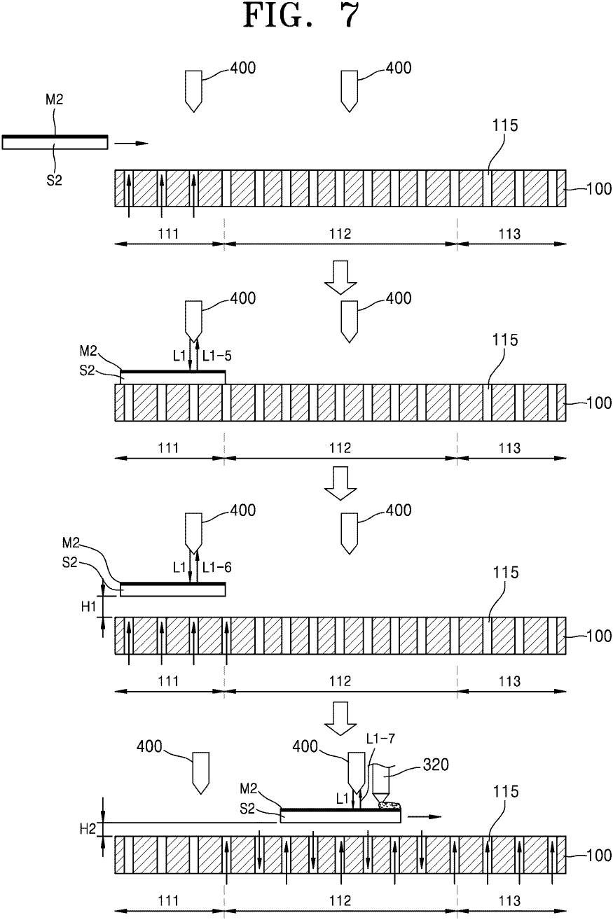

The measurement unit 400 may measure floating amounts or floating heights of substrates by applying different reference signal data based on serial numbers of the substrates. The measurement unit 400 may measure floating amounts or floating heights of substrates having the same serial number, by applying the same reference signal data to the substrates. The reference signal data may be pre-stored in the controller 500. Alternatively, a procedure of obtaining specific reference signal data for a specific serial number may be additionally performed (see FIG. 7). FIG. 6 is used to describe an example in which the controller 500 has reference signal data for a substrate S1 on which a layer M1 is formed.

Referring to the first view of FIG. 6, a substrate S1 on which a layer M1 is formed may enter the substrate floating unit 100 (or the stage 110). The holes 115 of the loader 111 may provide a gas pressure to float the substrate S1. The substrate S1 may move along the first direction 12 while being partially grabbed by the grabbing member 220 and floated from a top surface of the stage 110. The controller 500 may obtain a serial number of the substrate S1 and apply, to the measurement unit 400, reference signal data corresponding to the serial number.

Then, referring to the second view of FIG. 6, the measurement unit 400 may measure a floating amount or floating height H1 of the substrate S1 while the substrate S1 is moving. The measurement of the floating amount H1 of the substrate S1 by the measurement unit 400 may be performed intermittently or continuously. The measurement unit 400 may irradiate a beam L1 onto the substrate S1 and measure a signal of a reflected beam L1-3. In this case, the controller 500 may calculate the floating amount H1 of the substrate S1 by applying the reference signal data to a difference between the irradiated beam L1 and the reflected beam L1-3.

Then, referring to the third view of FIG. 6, the substrate S1 may be coated with a liquid chemical while moving from the loader 111 to the coater 112 along the first direction 12. When the substrate S1 reaches the nozzle 320, the nozzle 320 may eject the liquid chemical onto the substrate S1. The substrate S1 may be coated with the liquid chemical on the entirety of a top surface thereof while continuously floating and moving in the first direction 12 under the nozzle 320.

The floating amount of the substrate S1 may also be measured by the measurement unit 400 during the process of coating the substrate S1. To this end, a plurality of measurement units 400 may be provided. Particularly, the measurement unit 400 may be disposed above a path before the nozzle 320 in a path along which the substrate S1 moves in the first direction 12.

According to an embodiment, when the floating amount H1 of the substrate S1 measured by the measurement unit 400 differs from a desired set floating amount H2, the floating amount of the substrate S1 may be adjusted (H1 → H2). The controller 500 may control the pressure providing member 170 to control a value of a gas pressure or vacuum pressure provided from the holes 115. In order to finely control the value of the gas pressure or vacuum pressure, the pressure providing member 170 may include an electronic valve.

After the process of coating and moving the substrate S1 on which the layer M1 is formed is finished, a subsequent substrate S may enter the substrate floating unit 100 (or the stage 110). When this substrate S is the substrate S1 on which the layer M1 is formed as in the previous process, the procedure of FIG. 6 may be equally performed and the measurement unit 400 may measure a floating amount by applying the same reference signal data. When this substrate S is a substrate S2 on which a layer M2 is formed unlike the previous process, the controller 500 may obtain a serial number of the substrate S2 and then find reference signal data corresponding to the serial number. The controller 500 may apply the reference signal data to the measurement unit 400 to measure a floating amount.

FIG. 7 includes cross-sectional views showing a substrate transfer procedure and a floating amount measurement procedure, according to another embodiment of the present invention.

The controller 500 may obtain a serial number of a substrate S. The measurement unit 400 may measure floating amounts or floating heights of substrates by applying different reference signal data based on serial numbers of the substrates. FIG. 7 shows a procedure in which the controller 500 obtains reference signal data when reference signal data corresponding to a serial number does not exist.

Referring to the first view of FIG. 7, a substrate S2 on which a layer M2 is formed may enter the substrate floating unit 100 (or the stage 110). The holes 115 of the loader 111 may provide a gas pressure to float the substrate S2. The substrate S2 may move along the first direction 12 while being partially grabbed by the grabbing member 220 and floated from a top surface of the stage 110. The controller 500 may obtain a serial number of the substrate S2 and apply, to the measurement unit 400, reference signal data corresponding to the serial number.

Referring to the second view of FIG. 7, when the reference signal data corresponding to the serial number does not exist, the substrate S2 on which the layer M2 is formed may be brought into contact with or adsorbed onto the substrate floating unit 100 (or the stage 110). When the reference signal data corresponding to the serial number does not exist, the controller 500 may bring or adsorb the substrate S2 into contact with or onto the substrate floating unit 100 (or the stage 110) by controlling the gas pressure of the holes 115 of the loader 111.

Then, the measurement unit 400 may irradiate a beam L1 onto the substrate S2 and measure a signal of a reflected beam L1-5. The controller 500 may obtain reference signal data based on a difference between the irradiated beam L1 and the reflected beam L1-5. The obtained reference signal data may be mapped to the serial number of the substrate S2. The controller 500 may store the obtained reference signal data mapped to the serial number.

Meanwhile, the substrate S2 may be brought into contact with or adsorbed onto the substrate floating unit 100 (or the stage 110) on the coater 112 next to the loader 111. In this case, the substrate S2 needs to be brought into contact with or adsorbed onto the substrate floating unit 100 (or the stage 110) before reaching the nozzle 320. The reference signal data may be obtained using the measurement unit 400 disposed above the coater 112 and above a path before the nozzle 320.

Then, referring to the third view of FIG. 7, the substrate S2 may be floated and moved along the first direction 12 by providing a gas pressure to the holes 115. The measurement unit 400 may measure a floating amount or floating height H1 of the substrate S2 while the substrate S2 is moving. The measurement of the floating amount H1 of the substrate S2 by the measurement unit 400 may be performed intermittently or continuously. The measurement unit 400 may irradiate a beam L1 onto the substrate S2 and measure a signal of a reflected beam L1-6. In this case, the controller 500 may calculate the floating amount H1 of the substrate S2 by applying the reference signal data to a difference between the irradiated beam L1 and the reflected beam L1-6.

Meanwhile, according to an embodiment, the substrates S1 and S2 may be controlled to be floated to the same height. In other words, the gas pressures or vacuum pressures provided from the holes 115 to the substrates S1 and S2 may be controlled to be the same. However, different reference signal data may be set for the serial numbers of the substrates S1 and S2 such that the measurement unit 400 may apply different zero point data or correction parameters for calculating the floating amounts of the substrates S1 and S2.

Then, referring to the fourth view of FIG. 7, the substrate S2 may be coated with a liquid chemical while moving from the loader 111 to the coater 112 along the first direction 12. When the substrate S2 reaches the nozzle 320, the nozzle 320 may eject the liquid chemical onto the substrate S2. The substrate S2 may be coated with the liquid chemical on the entirety of a top surface thereof while continuously floating and moving in the first direction 12 under the nozzle 320.

The floating amount of the substrate S2 may also be measured by the measurement unit 400 during the process of coating the substrate S2. To this end, a plurality of measurement units 400 may be provided. Particularly, the measurement unit 400 may be disposed above a path before the nozzle 320 in a path along which the substrate S2 moves in the first direction 12.

According to an embodiment, when the floating amount H1 of the substrate S2 measured by the measurement unit 400 differs from a desired set floating amount H2, the floating amount of the substrate S2 may be adjusted (H1 → H2). The controller 500 may control the pressure providing member 170 to control a value of a gas pressure or vacuum pressure provided from the holes 115. In order to finely control the value of the gas pressure or vacuum pressure, the pressure providing member 170 may include an electronic valve.

After the process of coating and moving the substrate S2 on which the layer M2 is formed is finished, a subsequent substrate S may enter the substrate floating unit 100 (or the stage 110). When reference signal data corresponding to a serial number of the substrate S exists, the procedure of FIG. 6 may be performed. When reference signal data corresponding to a serial number of the substrate S does not exist, the procedure of FIG. 7 may be performed to obtain and store reference signal data corresponding to the new serial number.

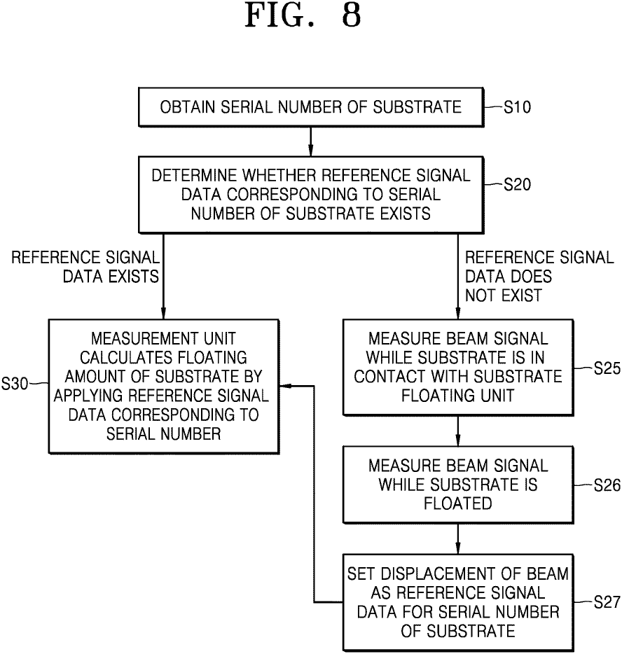

FIG. 8 is a flowchart of a substrate floating amount measurement method according to an embodiment of the present invention.

Initially, the controller 500 may obtain a serial number of a substrate S entering the substrate floating unit 100 (or the stage 110) (S10).

Then, the controller 500 may determine whether reference signal data corresponding to the serial number of the substrate S exists (S20).

When the reference signal data corresponding to the serial number of the substrate S exists, the measurement unit 400 may calculate a floating amount of the substrate S by applying the reference signal data to a beam irradiated onto the substrate S and a reflected beam signal (S30).

When the reference signal data corresponding to the serial number of the substrate S does not exist, a procedure of obtaining reference signal data may be further performed.

Initially, a beam signal may be measured while the substrate S is in contact with or adsorbed on the substrate floating unit 100 (or the stage 110) (S25). Reference signal data may be obtained based on a difference between the beam irradiated onto the substrate S and the reflected beam signal.

Then, a beam signal may be measured while the substrate S is floated (S26). After that, reference signal data may be obtained based on a displacement between the beam signal reflected when the substrate S is in contact with or adsorbed on the substrate floating unit 100 and the beam signal reflected when the substrate S is floated (S27). The reference signal data may be obtained by performing step S25 alone or together with steps S26 and S27.

When reference signal data for a specific serial number is obtained, the measurement unit 400 may calculate a floating amount of the substrate S by applying the reference signal data to a beam irradiated onto the substrate S and a reflected beam signal (S30).

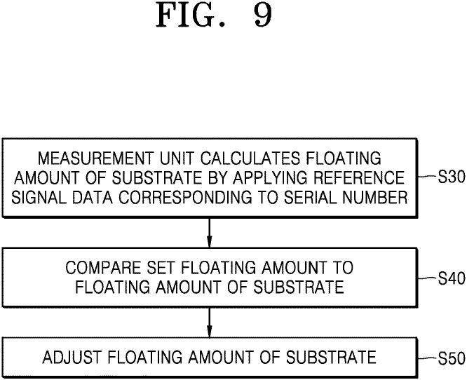

FIG. 9 is a flowchart of a substrate floating amount adjustment method according to an embodiment of the present invention.

Initially, in a procedure of moving the substrate S along the first direction 12 above the substrate floating unit 100, the measurement unit 400 may intermittently or continuously measure a floating amount of the substrate S by applying reference signal data corresponding to a serial number of the substrate S (S30).

Then, the controller 500 may compare a desired set floating amount to a current floating amount of the substrate S (S40).

When the desired set floating amount is the same as the current floating amount of the substrate S, a process of moving and coating the substrate S may be performed. When the desired set floating amount is different from the current floating amount of the substrate S, the floating amount of the substrate S may be adjusted (S50). The controller 500 may control the pressure providing member 170 to control a value of a gas pressure or vacuum pressure provided from the holes 115.

As described above, according to the substrate processing apparatus 1 and the substrate floating amount measurement method of the present invention, because reference signal data of the measurement unit 400 is changed and applied regardless of the type of the layer M1 or M2 provided on the substrate S1 or S2, a floating amount may be precisely measured. In addition, as described above in relation to FIG. 7, when reference signal data corresponding to a serial number does not exist, a reference signal data obtaining process may be performed only once. Therefore, a measurement error due to a reflectivity of a substrate may be prevented by minimizing a procedure of setting a zero point of a floating amount measurement apparatus, which needs to be performed based on the type of the substrate. Furthermore, a liquid chemical may be coated with a uniform thickness and process failure, e.g., a collision between a nozzle and the substrate, may be prevented by precisely measuring a floating amount and thoroughly monitoring every process.

As described above, according to an embodiment of the present invention, a floating amount may be precisely measured regardless of the type of a layer formed on a substrate.

In addition, according to an embodiment of the present invention, a measurement error due to a reflectivity of a substrate may be prevented by minimizing a procedure of setting a zero point of a floating amount measurement apparatus, which needs to be performed based on the type of the substrate.

Furthermore, according to an embodiment of the present invention, process failure may be prevented by precisely measuring a floating amount and thoroughly monitoring every process.

However, the scope of the present invention is not limited to the above effects.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A substrate processing apparatus comprising:
a substrate floating unit for floating a substrate;
a nozzle unit positioned above the substrate floating unit to eject a liquid chemical onto the substrate;
a measurement unit for measuring a floating amount of the substrate; and
a controller for obtaining a serial number of the substrate and providing control to change, based on the serial number, reference signal data used by the measurement unit to measure the floating amount of the substrate.

2. The substrate processing apparatus of claim 1, wherein the measurement unit measures the floating amount of the substrate by measuring a reflected signal of a beam irradiated onto the substrate.

3. The substrate processing apparatus of claim 2, wherein the measurement unit measures the floating amount of the substrate by measuring a signal of the beam from a height at which the substrate is in contact with the substrate floating unit to a height to which the substrate is floated.

4. The substrate processing apparatus of claim 2, wherein the measurement unit irradiates a laser beam onto the substrate.

5. The substrate processing apparatus of claim 2, wherein the reference signal data is set based on a difference in reflectivity for the beam between layers formed on different substrates.

6. The substrate processing apparatus of claim 2, wherein the controller measures floating amounts of substrates having the same serial number, by applying the same reference signal data.

7. The substrate processing apparatus of claim 2, wherein, when reference signal data corresponding to a specific serial number of the substrate does not exist, the controller measures a signal of the beam from a height at which the substrate is in contact with the substrate floating unit to a height to which the substrate is floated, and sets a displacement of the beam due to a change of the substrate as reference signal data for the serial number.

8. The substrate processing apparatus of claim 7, wherein all substrates are controlled to be floated to the same height, and different reference signal data are set for different serial numbers.

9. The substrate processing apparatus of claim 7, wherein the controller sets reference signal data for the serial number of the substrate and, when reference signal data corresponding to a specific serial number exists, the measurement unit measures the floating amount of the substrate by applying the reference signal data.

10. The substrate processing apparatus of claim 1, wherein the substrate floating unit comprises:
a stage having a top surface provided with a plurality of holes; and
a pressure providing member for providing a gas pressure or vacuum pressure through the holes to above the stage.

11. The substrate processing apparatus of claim 10, wherein the stage comprises a loader, a coater, and an unloader, and
wherein the nozzle unit ejects the liquid chemical onto the substrate from above the coater.

12. The substrate processing apparatus of claim 11, wherein at least one measurement unit is disposed above the coater.

13. The substrate processing apparatus of claim 11, wherein, when reference signal data corresponding to a specific serial number of the substrate does not exist, the measurement unit used to set the reference signal data is disposed above the loader or above a path on the coater before the nozzle unit.

14. A method of measuring a floating amount of a substrate in a substrate processing apparatus comprising a substrate floating unit for floating the substrate, a nozzle unit positioned above the substrate floating unit to eject a liquid chemical onto the substrate, and a measurement unit for measuring the floating amount of the substrate, the method comprising:
obtaining a serial number of the substrate; and
providing control to change, based on the serial number, reference signal data used by the measurement unit to measure the floating amount of the substrate.

15. The method of claim 14, wherein the floating amount of the substrate is measured by irradiating a beam onto the substrate and measuring a reflected signal by using the measurement unit.

16. The method of claim 14, wherein the reference signal data is set based on a difference in reflectivity for the beam between layers formed on substrates having different serial numbers.

17. The method of claim 14, wherein floating amounts of substrates having the same serial number are measured by applying the same reference signal data.

18. The method of claim 14, further comprising:
(a) obtaining the serial number of the substrate;
(b) determining whether reference signal data corresponding to the serial number of the substrate exists; and
(c) measuring, by the measurement unit, the floating amount of the substrate by applying the reference signal data corresponding to the serial number,
wherein step (b) comprises, when the reference signal data corresponding to the serial number of the substrate does not exist, measuring a signal of a beam from a height at which the substrate is in contact with the substrate floating unit to a height to which the substrate is floated, and setting a displacement of the beam due to a change of the substrate as reference signal data for the serial number.

19. The method of claim 18, further comprising (d) adjusting the floating amount of the substrate in such a manner that all substrates are floated to the same height.

20. A method of measuring a floating amount of a substrate in a substrate processing apparatus comprising a substrate floating unit for floating the substrate, a nozzle unit positioned above the substrate floating unit to eject a liquid chemical onto the substrate, and a measurement unit for measuring the floating amount of the substrate, the method comprising:
(a) obtaining a serial number of the substrate;
(b) determining whether reference signal data corresponding to the serial number of the substrate exists; and
(c) measuring, by the measurement unit, the floating amount of the substrate by applying the reference signal data corresponding to the serial number,
wherein step (c) comprises measuring the floating amount of the substrate by irradiating a laser beam onto the substrate and measuring a reflected signal by using the measurement unit, wherein the reference signal data is set based on a difference in reflectivity for the laser beam between layers formed on substrates having different serial numbers,
wherein step (b) comprises, when the reference signal data corresponding to the serial number of the substrate does not exist, measuring a signal of the laser beam from a height at which the substrate is in contact with the substrate floating unit to a height to which the substrate is floated, and setting a displacement of the laser beam due to a change of the substrate as reference signal data for the serial number, and
wherein floating amounts of substrates having the same serial number are measured by applying the same reference signal data.
